(19) United States
(12) Patent Application Publication
(10) Pub. No.: US 2007/0166972 A1
(43) Pub. Date: Jul. 19, 2007

(54) SEMICONDUCTOR DEVICE AND MANUFACTURING METHOD

(76) Inventor: Young-Tack Park, Seoul (KR)

Correspondence Address: SHERR & NOURSE, PLLC, 620 HERNDON PARKWAY, SUITE 200, HERNDON, VA, 20170, US

(21) Appl. No.: 11/617,235

(22) Filed: Dec. 28, 2006

(30) Foreign Application Priority Data
Dec. 29, 2005 (KR) 10-2005-0134052
Dec. 29, 2005 (KR) 10-2005-0134053

(51) Int. Cl. H01L 21/3205; H01L 29/94

(52) U.S. Cl. 438/589; 257/330

(57) ABSTRACT

A semiconductor substrate includes a plurality of isolation regions formed therein and having a trench in a region between the isolation wells, a gate insulating layer formed within the trench, a gate electrode formed on the gate insulating layer filling the trench, and source and drain electrodes formed on the substrate between the gate electrode and the isolation wells.

The present application claims priority under 35 U.S.C. 119 and 35 U.S.C. 365 to Korean Patent Application No. 10-2005-0134052 (filed on Dec. 29, 2005) and to Korean Patent Application No. 10-2005-0134053 (filed on Dec. 29, 2005), which are both hereby incorporated by reference in their entirety.

### BACKGROUND

Embodiments relate to semiconductor devices and manufacturing methods of semiconductor devices. Transistors may have a gate, source and drain in a device region defined by a local oxidation of silicon (LOCOS) method or swallow trench isolation (STI) method.

In general, a transistor may have a structure as shown in FIG. 1. The transistor includes a gate electrode 220 formed on a substrate 200 in which STI layers 210 are formed. A source electrode 230 and a drain electrode 240 are formed within the substrate at both sides of the gate electrode 220.

A method of fabricating the transistor of FIG. 1 will be described below. A gate insulating layer is first formed on a semiconductor substrate in which STI layers are formed. A polysilicon layer is deposited on the gate insulating layer. The STI layers serve to electrically isolate separate transistors or other devices formed in the semiconductor substrate, thereby preventing malfunctions between the devices.

A photolithography process is performed on the gate insulating layer and the polysilicon layer to form a gate electrode. After this process, the gate electrode is formed between the STI layers. Thereafter, using the gate electrode as a mask, an ion implantation apparatus implants highly concentrated impurity ions into an exposed, active region of the semiconductor substrate, thereby forming source and drain junction regions at both sides of the gate electrode.

A relatively high level of integration of semiconductor devices may increase the number of transistors integrated onto one substrate. As semiconductor devices are miniaturized, critical dimensions (CD) of gate electrodes may become relatively small. Relatively small critical dimensions of gate electrodes may result in shortened channel lengths below the gate electrodes. Ions, which may be implanted by forming and annealing source and drain electrodes using gate electrodes as a mask, may become laterally diffused. Lateral diffusion of ions may shorten channel length. If channel length is shortened, threshold voltage Vₜₕ of a transistor may be lowered and leakage current may increase.

### SUMMARY

Embodiments relate to a transistor with a relatively long channel length. In embodiments, a transistor with a relatively long channel length may have relatively high performance. Embodiments relate to a method of manufacturing a transistor with a relatively long channel length.

In accordance with embodiments, a semiconductor device is provided, including a semiconductor substrate having a plurality of isolation regions formed therein and having a trench in a region between the isolation wells. A gate insulating layer is formed within the trench, and a gate electrode is formed on the gate insulating layer, the gate electrode filling the trench. Source and drain electrodes are formed on the substrate between the gate electrode and the isolation wells.

In accordance embodiments, a method of manufacturing a semiconductor device includes forming a trench in a substrate in which a plurality of isolation regions are formed, forming a gate insulating layer within the trench, forming a gate electrode filling the trench on the gate insulating layer, and forming source and drain electrodes on the substrate between the gate electrode and the isolation wells.

### BRIEF DESCRIPTION OF THE DRAWINGS

FIG. 1 illustrates a cross-sectional view of a semiconductor device.

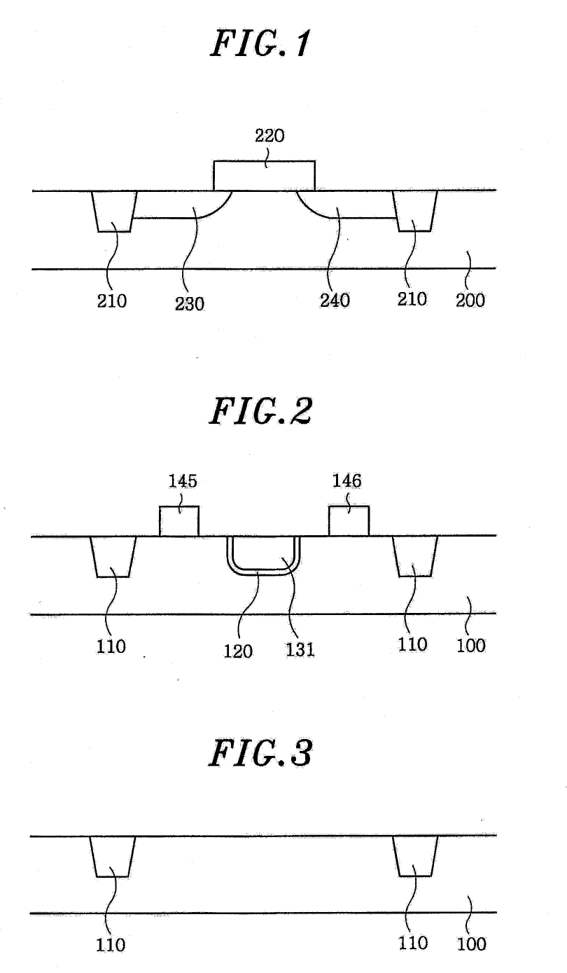

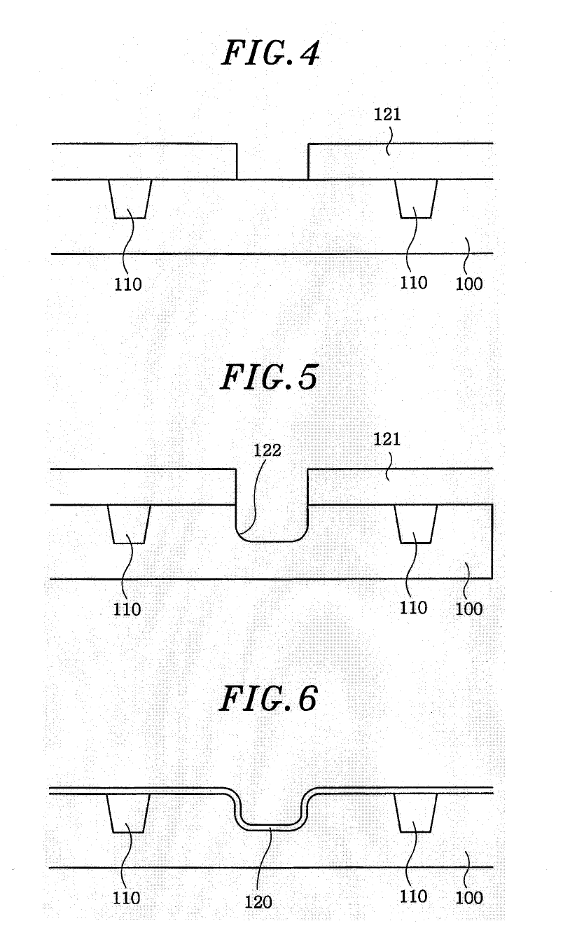

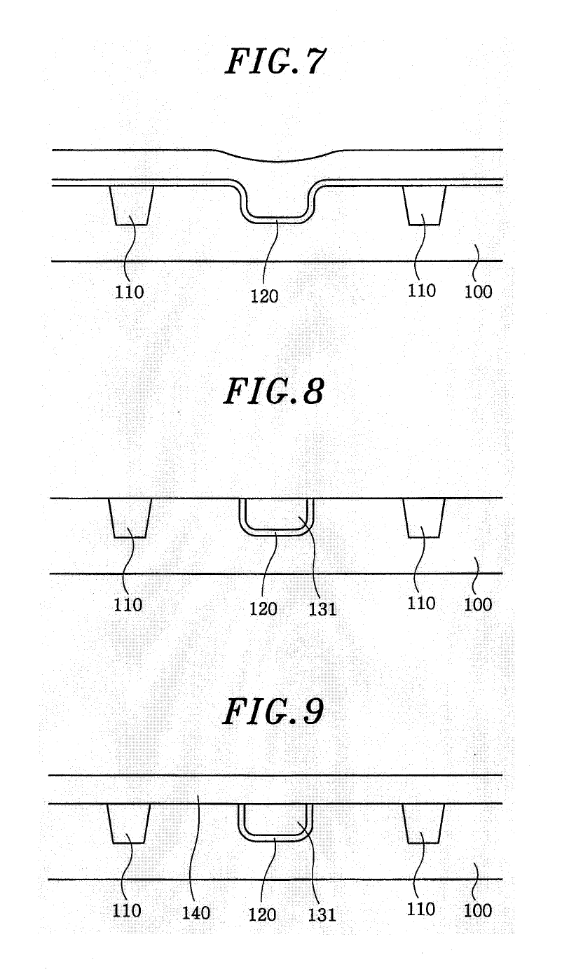

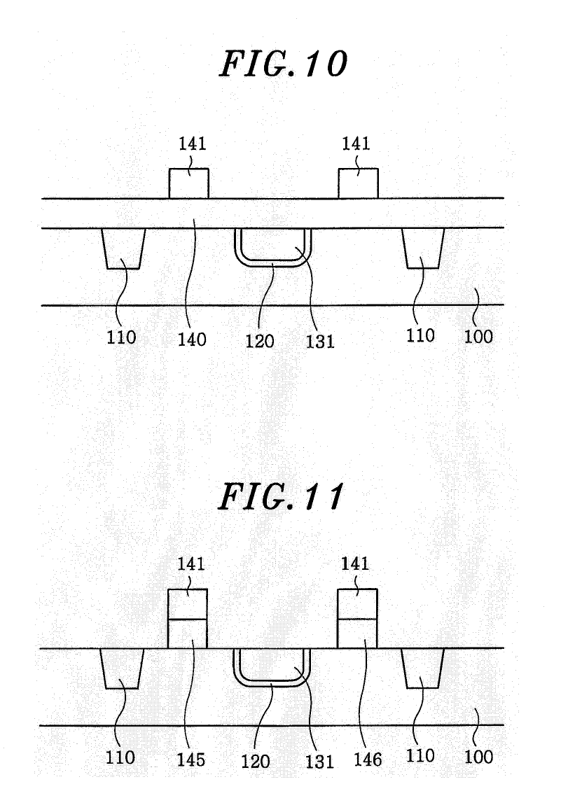

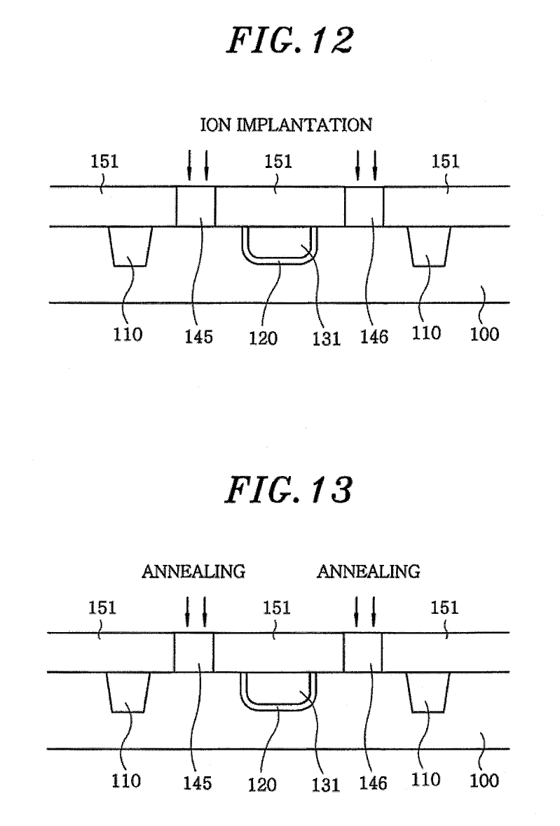

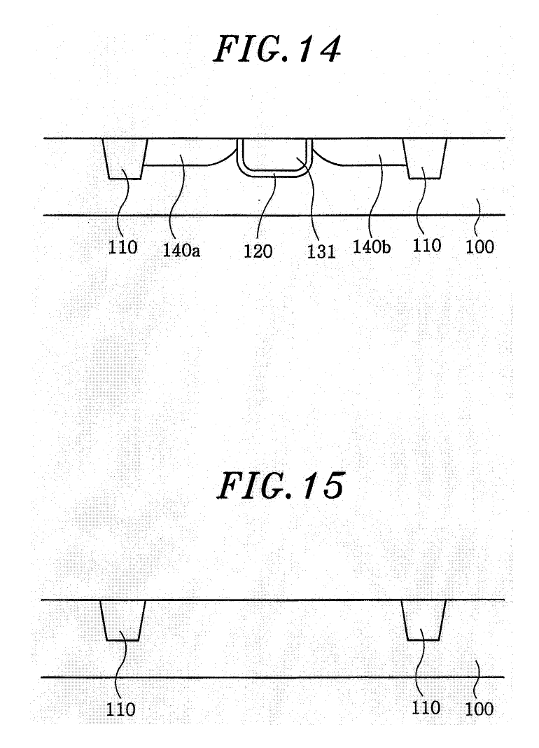

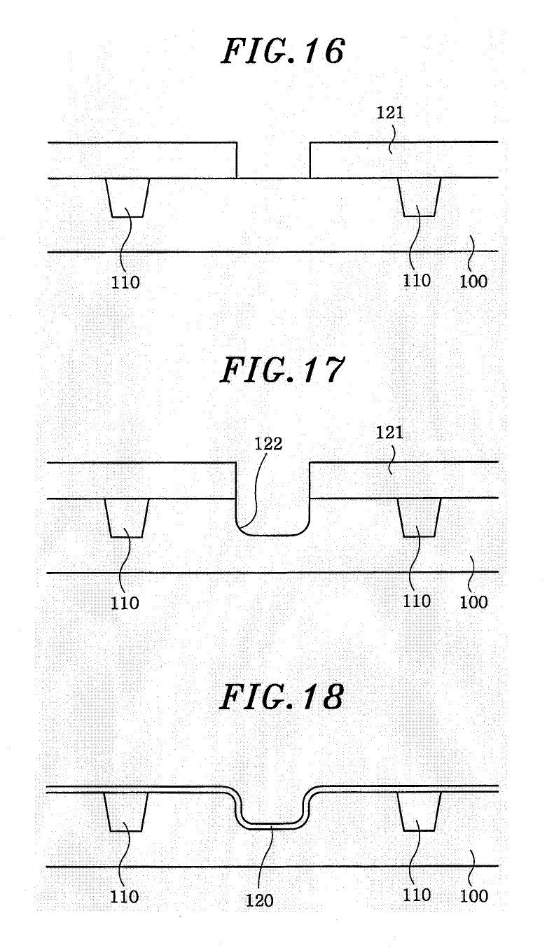

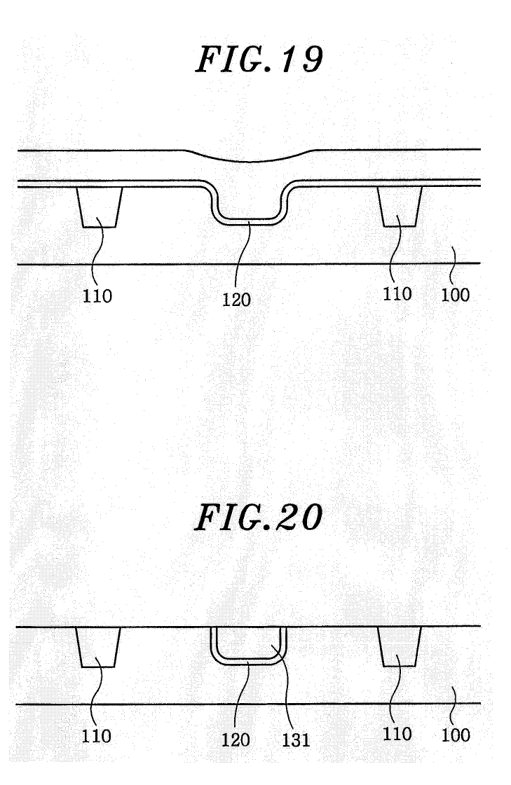

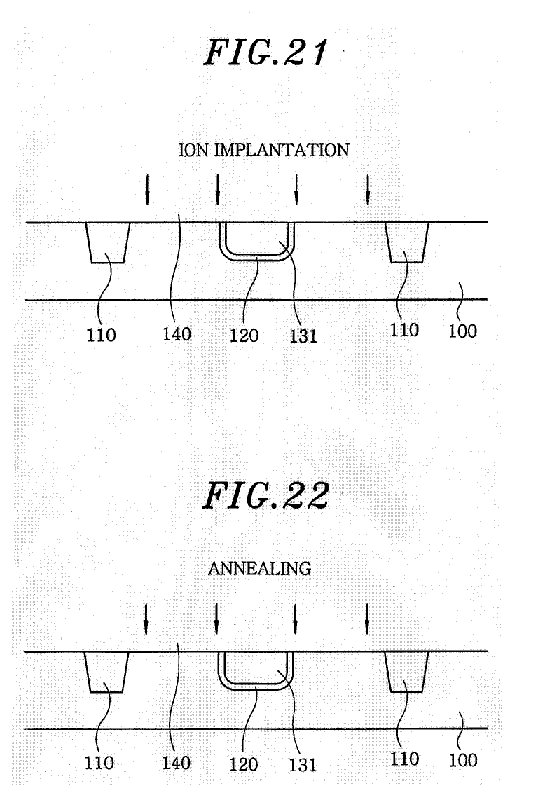

Example FIG. 2 illustrates a cross-sectional view of a semiconductor device, in accordance with embodiments.

Example FIGS. 3 to 13 are cross-sectional views illustrating a method of manufacturing a semiconductor device, in accordance with embodiments.

Example FIG. 14 illustrates a cross-sectional view of a semiconductor device, in accordance with embodiments.

Example FIGS. 15 to 22 are cross-sectional views illustrating a method of manufacturing a semiconductor device, in accordance with embodiments.

### DETAILED DESCRIPTION

To clarify multiple layers and regions, the thickness of the layers is enlarged in the drawings. Like reference numerals designate like elements throughout the specification. When it is said that any part, such as a layer, film, area, or plate, is positioned on another part, it means the part is directly on the other part or above the other part with at least one intermediate part. On the other hand, if any part is said to be positioned directly on another part it means that there is no intermediate part between the two parts.

As shown in FIG. 2, a plurality of isolation wells 110 are formed in a substrate 100. The isolation wells 110 serve to electrically isolate from each other the individual transistors formed in the substrate 100.

A trench 122 is formed in the substrate 100 between the isolation wells 110. A gate oxide layer 120 is formed on the trench 122. A gate electrode 131 is formed on the gate oxide layer 120. The gate electrode 131 fills the trench 122 of the substrate 100. The surface of the gate electrode 131 is coplanar with the surface of substrate 100 in regions where the gate electrode 131 is not formed.

A source electrode 145 and a drain electrode 146 are formed on regions between the isolation wells 110 and gate electrode 131. According to embodiments, the source electrode 145 and the drain electrode 146 are not formed in the substrate, but formed on the substrate 100 as described above.

As described above with reference to FIG. 2, the semiconductor device includes the gate electrode 131 filling trench 122 in the substrate 100, and the source electrode 145 and drain electrode 146 formed on the substrate 100 beside the gate electrode 131.

As set forth above, the gate electrode 131 is formed in the substrate 100. Accordingly, a channel length below the gate electrode 131 can be controlled by the depth or width of the trench 122 in which the gate electrode 131 is formed.

Furthermore, the gate electrode 131 is formed in the substrate, and the source electrode 145 and the drain electrode 146 are formed on the substrate 100 as described above. Accordingly, when the source electrode 145 and the drain electrode 146 are formed, it is possible to effectively prevent ions from diffusing into the region in which the gate electrode is formed in the process of annealing the implanted ions.

A method of manufacturing the semiconductor device will be described below with reference to FIGS. 3 to 13. Referring to FIG. 3, the plurality of isolation wells 110 are formed in the substrate 100. To form the isolation wells 110, a trench is formed in the substrate 100 and it is then filled with an insulating material.

Referring next to FIG. 4, masks 121 are prepared on the substrate 100 in which the plurality of isolation wells 110 are formed, leaving a region in which the gate electrode will be formed. The substrate 100 is etched using the masks 121, thereby forming the trench 122 in which the gate electrode will be formed in the substrate 100, as shown in FIG. 5. The trench 122 may be formed in a U shape or a V shape.

Referring to FIG. 6, the masks 121 are removed, and a gate oxide layer 120 is deposited on the entire surface of the substrate 100. As shown in FIG. 7, a polycrystalline silicon layer 130 is formed on the gate oxide layer 120. Alternatively, instead of the polycrystalline silicon layer 130, a single crystalline silicon layer may be deposited on the gate oxide layer 120 using an epitaxial growth method.

Thereafter, the substrate 100 on which the gate oxide layer 120 and the polycrystalline silicon layer 130 are formed is planarized by a Chemical Mechanical Polishing (CMP) method. The gate electrode 131 now fills only the trench 122 of the substrate 100 as shown in FIG. 8. In this regard, the surface of the gate electrode 131 is approximately the same height as the substrate 100 of the regions surrounding the gate electrode 131.

Next, a polycrystalline silicon layer 140 is deposited on the entire surface as shown in FIG. 9. Then, masks 141 are prepared on regions in which source and drain electrodes will be formed, as shown in FIG. 10. Etching is performed using the masks 141, thereby forming desired patterns of the source electrode 145 and the drain electrode 146, as shown in FIG. 11. The masks 141 are then removed.

As illustrated in FIG. 12, masks 151, which have inverse patterns to the masks 141, are prepared on the substrate 100 around the source electrode 145 and the drain electrode 146. Impurity ions are then implanted into only the source electrode and the drain electrode 146 by employing the masks 151.

Thereafter, as shown in FIG. 13, the patterns of the source electrode 145 and the drain electrode 146 into which the impurity ions are implanted are annealed using the masks 151, thereby completing the source electrode 145 and the drain electrode 146 as shown in FIG. 2.

In embodiments, after the patterns of the source electrode 145 and the drain electrode 146 are formed, the source electrode 145 and the drain electrode 146 are completed through the ion implantation and annealing using the masks. One of ordinary skill in the art would appreciate other methods of manufacturing the semiconductor devices.

In embodiments, the gate electrode 131 filling the trench 122 of the substrate 100 may be formed first. The polycrystalline silicon layer 140 may then be formed over the substrate 100. The impurity ions may be implanted into the entire surface of the laminated polycrystalline silicon layer 140. After annealing, the masks 141 may be prepared and used to etch out the source electrode 145 and the drain electrode 146.

If the trench formed in the substrate is filled with the gate electrode as described above, a channel between the source region and the drain region at both sides of the gate electrode is defined below the gate electrode. Accordingly, the channel length may be controlled by the depth or width of the trench in which the gate electrode is formed according to a characteristic size of each semiconductor device.

Furthermore, if the gate electrode is formed in the trench formed in the substrate, and the source electrode and the drain electrode are formed on the substrate at both sides of the gate electrode, it is possible to effectively prevent impurity ions implanted in the source and drain electrodes from laterally diffusing toward the gate electrode. In accordance with embodiments, a reduction of the channel length due to this lateral diffusion of impurity ions may be prevented without changing the characteristic size of the transistor.

FIG. 14 is a cross-sectional view of a semiconductor device according to embodiments. As illustrated in FIG. 14, a plurality of isolation wells 110 are formed in a substrate 100. The isolation wells 110 serve to electrically isolate from each other the individual transistors formed in the substrate 100.

A trench 122 is formed in the substrate 100 between the isolation wells 110. A gate oxide layer 120 is formed on the trench 122. A gate electrode 131 is formed on the gate oxide layer 120. The gate electrode 131 fills the trench 122 of the substrate 100. The surface of the gate electrode 131 is coplanar with the surface of substrate 100 in regions where the gate electrode 131 is not formed.

A source electrode 140a and a drain electrode 140b are formed in the substrate 100 between the isolation wells 110, at both sides of the gate electrode 131 that fills the trench 122. If the gate electrode 131 is formed in the substrate 100, and the source region 140a and the drain region 140b are formed at both sides of the gate electrode 131, the region below the trench 122 is defined as a channel region. Accordingly, the channel length below the gate electrode 131 may be controlled by controlling the depth or width of the trench 122 containing the gate electrode 131.

Furthermore, with the gate electrode 131 formed within the substrate, implanted impurity ions may be prevented from laterally diffusing towards the gate electrode during the annealing of the impurity ions when the source region 140a and the drain region 140b are formed.

A method of manufacturing the semiconductor device according to embodiments will be described below with reference to FIGS. 15 to 22. A portion of the method of manufacturing the semiconductor device shown in FIGS. 15 to 22 is the same as shown in FIGS. 3 to 13. Accordingly, the processes in FIGS. 15 to 20 duplicative of those in FIGS. 3 to 8 will not be described for the sake of brevity and simplicity.

Referring now to FIG. 21, impurity ions are implanted into a substrate 100 on the sides of a gate electrode 131 by using isolation wells 110 and the gate electrode 131 formed in the substrate 100 as masks. The substrate into which the impurity ions are implanted is then annealed, as shown in FIG. 22, thereby completing the source region 140a and the drain region 140b as shown in FIG. 14.

As described above, the channel length, in the region below the gate electrode, can be made sufficiently long by controlling the shape, depth or width of the trench in which the gate electrode is formed according to a characteristic size of each semiconductor device.

Furthermore, impurity ions implanted when the source and drain electrodes are formed can be prevented from laterally diffusing toward the gate electrode even in the annealing process. It is therefore possible to prevent a channel length reduction due to the lateral diffusion of impurity ions without changing the characteristic size of transistors in a semiconductor device.

It will be apparent to those skilled in the art that various modifications and variations can be made to embodiments. Thus, it is intended that embodiments cover modifications and variations thereof within the scope of the appended claims.

What is claimed is:

1. A semiconductor device, comprising:
a trench formed in a semiconductor substrate;
a gate electrode formed in the trench;
a gate insulating layer formed in the trench, wherein the gate electrode is formed over the gate insulating layer; and
a at least two isolation wells formed in the semiconductor substrate, wherein the trench is between the at least two isolation wells.

2. The semiconductor device of claim 1, wherein the source and drain electrodes are formed between the gate electrode and at least two isolation wells.

3. The semiconductor device of claim 1, wherein source and drain regions are formed in the semiconductor substrate.

4. The semiconductor device of claim 3, wherein the source and drain regions are formed between the gate electrode and at least two isolation wells.

5. The semiconductor device of claim 3, wherein a region in which the gate electrode is formed and regions in which the gate electrode is not formed are polished to have the same height.

6. The semiconductor device of claim 1, wherein the gate electrode comprises polycrystalline silicon.

7. The semiconductor device of claim 1, wherein the gate electrode comprises single crystalline silicon.

8. The semiconductor device of claim 1, wherein the trench has a V shape.

9. The semiconductor device of claim 1, wherein the trench has a U shape.

10. A method comprising:
forming a trench in a semiconductor substrate;
forming a gate electrode in the trench;
forming a gate insulating layer in the trench, wherein the gate electrode is formed over the gate insulating layer; and
forming a plurality of isolation wells in the semiconductor substrate.

11. The method of claim 10, comprising forming source and drain electrodes over the semiconductor substrate.

12. The method of claim 11, wherein said forming source and drain electrodes comprise forming source and drain electrodes between the gate electrode and at least two isolation wells.

13. The method of claim 11, wherein said forming the source and drain electrodes comprises:
depositing a polycrystalline silicon layer over the semiconductor substrate;
etching the polycrystalline silicon layer using a first mask to form an articulated polycrystalline silicon layer of source and drain electrode regions;
implanting impurity ions into the source and drain electrode regions on the polycrystalline silicon layer by using a second mask having an inverse pattern to that of the first mask; and
annealing the source and drain regions using the second mask.

14. The method of claim 11, wherein said forming the source and drain electrodes comprises:
depositing a polycrystalline silicon layer over the semiconductor substrate;
implanting impurity ions into the polycrystalline silicon layer;
annealing the polycrystalline silicon layer into which the impurity ions have been implanted; and
etching the annealed polycrystalline silicon layer using a mask to form the source and drain electrodes.

15. The method of claim 10, comprising forming source and drain regions in the semiconductor substrate.

16. The method of claim 15, wherein the gate electrode and isolation wells are formed through ion implantation and annealing.

17. The method of claim 10, wherein said forming the gate electrode comprises depositing a polycrystalline silicon layer.

18. The method of claim 10, wherein said forming the gate electrode comprises depositing a single crystalline silicon layer by an epitaxial growth method.

19. The method of claim 10, wherein the trench is formed in a U shape.

20. The method of claim 10, wherein the trench is formed in a V shape.
